(19) United States
(12) Patent Application Publication
(10) Pub. No.: US 2023/0132224 A1
(43) Pub. Date: Apr. 27, 2023

(54) Quantum-Confined Stark Effect Electro-Optic Modulator In Perovskite Quantum Wells Integrated On Silicon

(71) Applicant: Board of Regents, The University of Texas System, Austin, TX (US)

(72) Inventors: Alexander A. Demkov, Austin, TX (US); John Elliott Ortmann, Jr., Austin, TX (US); Agham Posadas, Round Rock, TX (US)

(21) Appl. No.: 17/908,599

(22) PCT Filed: Mar. 8, 2021
(86) PCT No.: PCT/US21/21362

§ 371 Date: Sep. 1, 2022

Related U.S. Application Data
(60) Provisional application No. 62/986,434, filed on Mar. 6, 2020.

(51) Int. Cl. H01L 33/06; H10K 85/30

(52) U.S. Cl. CPC H01L 33/06; H10K 85/30

(57) ABSTRACT

Electro-optic modulators and related devices and methods. The method includes forming a silicon dioxide layer on a silicon substrate. The method includes forming a doped silicon layer in or on the silicon dioxide layer. The method includes forming alternating layers of functional transition metal oxides (TMOs) on the doped silicon layer. Design parameters can be optimized to create realizable devices that minimize the energy consumption of, for example, a SrTiO₃/LaAlO₃ electro-optic modulator while maximizing electro-optic performance (e.g., modulation energies on the order of tens of pJ/bit).

### CROSS-REFERENCE TO RELATED APPLICATIONS

This application is national stage of International Patent Application No. PCT/US2021/021362 filed Mar. 8, 2021; which claims priority to U.S. Provisional Application No. 62/986,434 filed Mar. 6, 2020, each of which is incorporated herein by reference in its entirety for all purposes.

### STATEMENT REGARDING FEDERALLY SPONSORED RESEARCH

This invention was made with government support under Grant no. FA9550-18-1-0053 and Grant no. FA9550-12-1-0494 awarded by the Air Force Office of Scientific Research. The government has certain rights in the invention.

### TECHNICAL FIELD

Various embodiments of the present technology generally relate to quantum optics and electro-optic modulators. More specifically, some embodiments of the present technology relate to quantum-confined stark effect electro-optic modulators in perovskite quantum wells.

### BACKGROUND

Electro-optic modulators find use in a variety of applications. Most notable amongst these is in the construction of optical transceivers used in high-throughput data centers. Long-haul data transmission is best accomplished through optical fibers, while data transfer within computer chips is currently handled electronically. Optical transceivers, relying on electro-optic modulators, provide the interface between computer chips and long-haul fiber optic communication lines in high-throughput data centers and supercomputers. Competitive electro-optic modulators must be capable of operating at high data rates and must consume relatively little power.

### SUMMARY

Various embodiments of the present technology generally relate to electro-optic modulators. More specifically, some embodiments of the present technology relate to quantum-confined stark effect electro-optic modulators in strontium titanate (STO)/lanthanum aluminate (LAO) (SrTiO₃/LaAlO₃). While the SrTiO₃/LaAlO₃ materials system has garnered intense research interest over the past decade owing to the discovery of a two-dimensional electron gas at the interface of these two band insulators, recent reports have focused on its optical properties. The silicon-compatibility of the SrTiO₃/LaAlO₃ system, together with its large conduction band offset and the ability to confine charge carriers in SrTiO₃ quantum wells, makes it a potential candidate for use in a wide range of integrated photonics applications.

Some embodiments include multiple repeats of a semiconducting oxide quantum well material with low effective mass alternating with a barrier oxide material with large band gap and high dielectric constant. The entire stack can be integrated on a silicon substrate via a thin SrTiO₃ buffer layer. In some embodiments, a silicon-integrated oxide-based multiple quantum well structure can be based on a stannate perovskite as the well layer and a high-k dielectric as the barrier layer. The resulting quantum confined energy levels have separations that are in the visible light regime. Quantum well structures based on gallium arsenide (GaAs) have a shallow depth and are limited to the infrared regime. As such, various embodiments of the present technology can extend quantum well applications to the visible light regime. This can enable highly efficient laser diodes and photodetectors that can work with visible light.

A first aspect of the present disclosure provides a device. In a first embodiment, the device includes a silicon substrate, and a silicon dioxide layer formed on the silicon substrate. The device includes a doped silicon layer on which is built a heterostructure created from alternating functional layers of transition metal oxides (TMOs) and silicon. In an example, the “functional layers of TMOs,” which may also be referred to herein as “layers of functional TMOs,” consist of, or contain, one or more TMOs, and have defined electrical, optical, and/or other physical properties, which may be dictated, at least in part, by the composition and/or identity of particular TMOs used in the aforementioned layers.

In a second embodiment of the device according to the first aspect of the present disclosure, the TMOs may include strontium titanate. In the first, second, or in a third, embodiment of the device according to the first aspect of the present disclosure, the heterostructure may be a quantum well created from perovskite oxides as both barrier layers and quantum well layers.

In the first through third, or in a fourth, embodiment of the device according to the first aspect of the present disclosure, the barrier layers may be wide band gap, high dielectric constant materials. In the first through fourth, or in a fifth, embodiment of the device according to the first aspect of the present disclosure, the quantum well layers may be low effective mass, semiconducting oxides. In the first through fifth, or in a sixth, embodiment of the device according to the first aspect of the present disclosure, the low effective mass, semiconducting oxides may include stannate perovskites. In the first through sixth, or in a seventh, embodiment of the device according to the first aspect of the present disclosure, the semiconducting oxides may include barium stannate or strontium stannate. In the first through seventh, or in an eighth, embodiment of the device according to the first aspect of the present disclosure, the quantum well may confine electrons or holes in a dimension perpendicular to a surface of the heterostructure.

In the first through eighth, or in a ninth, embodiment of the device according to the first aspect of the present disclosure, the quantum well may have a depth of two to three electron volts. In the first through ninth, or in a tenth, embodiment of the device according to the first aspect of the present disclosure, the quantum well may have energy levels with a separation sufficient to enable visible light photon absorption or emission. In the first through tenth, or in an eleventh, embodiment of the device according to the first aspect of the present disclosure, the heterostructure created from the alternating functional layers of TMOs and silicon may create an electro-optic modulator.

In the first through eleventh, or in a twelfth, embodiment of the device according to the first aspect of the present disclosure, the heterostructure may be a hybrid silicon-TMO waveguide. In the first through twelfth, or in a thirteenth, embodiment of the device according to the first aspect of the present disclosure, the hybrid silicon-TMO waveguide may support a transverse magnetic optical mode. In the first through thirteenth, or in a fourteenth, embodiment of the device according to the first aspect of the present disclosure, the alternating functional layers of TMOs may be created via atomic layer deposition or molecular beam epitaxy.

In the first through fourteenth, or in a fifteenth, embodiment of the device according to the first aspect of the present disclosure, the doped silicon layer may be a heavily doped silicon layer. In an example, “doped silicon” has an added impurity (or impurities) which change(s) electrical, optical, and/or other physical properties as compared to undoped silicon, and which may be dictated, at least in part, by the composition and/or identity of particular impurities used in the doped silicon. The level of doping of doped silicon is often expressed as a number of impurity atoms, or ions (X), per cubic centimeter (cm³). Accordingly, “heavily doped silicon” and “lightly doped silicon” respectively mean doped silicon having comparatively different levels of impurity content. Thus, if heavily doped silicon has an impurity concentration of X₁ per cm³ and if lightly doped silicon has an impurity concentration of X₂ per cm³, X₁ is thus greater than X₂ in all cases. In some applications, X₁ and X₂ may be expressed as a range of impurity concentration, and X₁ (or a range thereof) may differ from X₂ (or a range thereof) by one or more orders of magnitude. Given the differing impurity concentrations, and electrical, optical, and/or other physical properties, of heavily doped, as compared to lightly doped, silicon, distinct layers of undoped, heavily doped, and lightly doped silicon in a device may provide differing electrical, optical, and/or other physical functions in the device.

In the first through fifteenth, or in a sixteenth, embodiment of the device according to the first aspect of the present disclosure, the device may further include a lightly doped silicon layer between the heavily doped silicon layer and the alternating functional layers of TMOs.

A second aspect of the present disclosure provides an electro-optic modulator. In a first embodiment, the electro-optic modulator includes a silicon substrate, and a silicon dioxide layer formed on the silicon substrate. The electro-optic modulator includes a doped silicon layer. The electro-optic modulator includes a thin film TMO heterostructure of multiple quantum wells created from alternating layers of strontium titanate and lanthanum aluminate built on the doped silicon layer. In a second embodiment of the electro-optic modulator according to the second aspect of the present disclosure, the multiple quantum wells may include barrier layers that are wide band gap, high dielectric constant materials. In the first, second, or in a third, embodiment of the electro-optic modulator according to the second aspect of the present disclosure, the multiple quantum wells may have quantum well layers formed of low effective mass, semiconducting oxides.

In the first through, third, or in a fourth, embodiment of the electro-optic modulator according to the second aspect of the present disclosure, the low effective mass, semiconducting oxides may include stannate perovskites. In the first through fourth, or in a fifth, embodiment of the electro-optic modulator according to the second aspect of the present disclosure, the low effective mass, semiconducting oxides may include barium stannate or strontium stannate. In the first through fifth, or in a sixth embodiment of the electro-optic modulator according to the second aspect of the present disclosure, the multiple quantum wells may confine electrons or holes in a dimension perpendicular to a surface of the thin film TMO heterostructure. In the first through sixth, or in a seventh, embodiment of the electro-optic modulator according to the second aspect of the present disclosure, at least some of the multiple quantum wells may have a depth of two to three electron volts.

In the first through seventh, or in an eighth, embodiment of the electro-optic modulator according to the second aspect of the present disclosure, at least some of the multiple quantum wells may have energy levels with a separation sufficient to enable visible light photon absorption or emission. In the first through eighth, or in a ninth, embodiment of the electro-optic modulator according to the second aspect of the present disclosure, the thin film TMO heterostructure may support a transverse magnetic optical mode allowing the electro-optic modulator to make use of intersubband absorptions. In the first through ninth, or in a tenth, embodiment of the electro-optic modulator according to the second aspect of the present disclosure, the doped silicon layer may be a heavily doped silicon layer. In the first through tenth, or in an eleventh, embodiment of the electro-optic modulator according to the second aspect of the present disclosure, the electro-optic modulator may further include a lightly doped silicon layer between the thin film TMO heterostructure. In the first through eleventh, or in a twelfth, embodiment of the electro-optic modulator according to the second aspect of the present disclosure, the thin film TMO heterostructure may provide quantum-confined Stark effect in intersubband absorption for electro-optic operation.

A third aspect of the present disclosure provides a method. In a first embodiment, the method includes the step of forming a silicon dioxide layer on a silicon substrate. The method includes the step of forming a doped silicon layer in or on the silicon dioxide layer. The method includes the step of forming alternating functional layers of TMOs on the doped silicon layer. In a second embodiment of the method according to the third aspect of the present disclosure, the doped silicon layer may include a heavily doped silicon layer, and the method may further include forming a lightly doped silicon layer on the heavily doped silicon layer. In the first, second, or in a third, embodiment of the method according to the third aspect of the present disclosure, the step of forming alternating functional layers of TMOs on the doped silicon layer may include forming the alternating functional layers of TMOs on the lightly doped silicon layer. In the first through third, or in a fourth, embodiment of the method according to the third aspect of the present disclosure, the method may further include the step of forming a layer of silicon on the doped silicon layer.

While multiple embodiments are disclosed, still other embodiments of the present technology will become apparent to those skilled in the art from the following detailed description, which shows and describes illustrative embodiments of the technology. As will be realized, the invention is capable of modifications in various aspects, all without departing from the scope of the present technology. Accordingly, the drawings and detailed description are to be regarded as illustrative in nature and not restrictive.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Embodiments of the present technology will be described and explained through the use of the accompanying drawings.

FIG. 1 illustrates an example of a heterostructure and corresponding energy levels according to one or more embodiments of the present technology.

FIGS. 2A and 2B are plots illustrating calculated wave functions and calculated absorption spectra according to one or more embodiments of the present technology.

FIGS. 3A and 3B are plots illustrating calculated absorption spectra and the change in absorption wavelength according to one or more embodiments of the present technology.

FIG. 4A illustrates an STO/LAO device structure according to one or more embodiments of the present technology.

FIG. 4B is a block diagram illustrating an STO/LAO quantum well heterostructure according to one or more embodiments of the present technology.

FIG. 5 illustrates a fundamental transverse magnetic (TM) mode confined in the quantum well region according to one or more embodiments of the present technology.

FIGS. 6A and 6B are plots illustrating electro-optic overlap and transition metal oxide (TMO) optical confinement in accordance with some embodiments of the present technology.

FIG. 7 is a plot illustrating simulated TMO optical confinement in accordance with one or more embodiments of the present technology.

FIGS. 8A and 8B are plots illustrating calculated switching energy and calculated additional optical absorption in accordance with some embodiments of the present technology.

FIG. 9A is an x-ray diffraction 2θ plot of a heterostructure built in accordance with one or more embodiments of the present technology.

FIG. 9B shows a cross-section transmission electron microscope image and chemical composition profile of the quantum well layers and LAO substrate according to some embodiments of the present technology.

FIGS. 10A and 10B are reflection high-energy electron diffraction (RHEED) patterns of an STO/LAO quantum well on silicon via an STO buffer layer in accordance with various embodiments of the present technology.

FIGS. 11A and 11B show scanning transmission electron microscopy (STEM) images with a clear STO/LAO separation of a heterostructure created in accordance with one or more embodiments of the present technology.

FIG. 12 illustrates an example of a basic vertical-cavity surface-emitting laser (VCSEL) in accordance with some embodiments of the present technology.

FIG. 13 is a flow chart of a method for manufacturing a quantum well heterostructure according to one or more embodiments of the present technology.

The drawings have not necessarily been drawn to scale. Similarly, some components and/or operations may be separated into different blocks or combined into a single block for the purposes of discussion of some of the embodiments of the present technology. Moreover, while the technology is amenable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

Various embodiments of the present technology generally relate to electro-optic modulators. More specifically, some embodiments of the present technology relate to quantum-confined stark effect electro-optic modulators in SrTiO₃/LaAlO₃. Electro-optic modulators play a key role in global communications and data transfer infrastructure. Most notably, electro-optic modulators form the basis for optical transceiver technologies which connect high throughput data centers to long-haul fiber optic communications lines. Due to rapidly expanding global data demands, the performance of such devices, as characterized by device speed and power consumption, is becoming increasingly critical for the efficient operation of global networks.

Most presently available electro-optic modulator technologies rely on the plasma dispersion effect for electro-optic operation. The plasma dispersion effect describes the impact of a changing charge carrier concentration on the effective refractive index of an optical signal. In addition, current optical transceiver technologies suffer from several drawbacks, including large power consumption, slow modulation speeds, and large device footprints.

In contrast, various embodiments of the present technology solve these problems by utilizing a fundamentally different physical phenomenon for electro-optic operation. Some embodiments include an SrTiO₃/LaAlO₃ quantum well heterostructure embedded within a silicon waveguide and electrically contacted via metallic electrodes. By utilizing the quantum-confined Stark effect, the energy levels of confined electronic states within the SrTiO₃ quantum wells can be modified, resulting in a shift in optical absorption strength at a given wavelength. Through this process of electric field-induced absorption modulation, electro-optic modulators can be constructed.

Various embodiments of the present technology can be characterized by a novel electro-optic modulation mechanism (quantum-confined Stark effect) and by the incorporation of novel materials (SrTiO₃/LaAlO₃) into a silicon photonics platform. Electro-optic modulation via the quantum-confined Stark effect promises faster operation than state-of-the-art plasma dispersion modulators. Furthermore, because the quantum-confined Stark effect is electric field-driven, rather than current-driven, operating power can be reduced significantly relative to state-of-the-art devices relying on current-driven phenomena for operation (e.g., plasma dispersion, thermo-optic). Finally, the ability to integrate SrTiO₃/LaAlO₃ with silicon substrates allows for the realization of compact, integrated devices, reducing device footprint.

Various embodiments of the present technology address the need for fast electro-optic modulators operating in the near-infrared for use in communications technologies. The quantum-confined Stark effect is an ultra-fast effect, in contrast to the plasma dispersion effect. Additionally, some embodiments do not necessitate current flow for operation, meaning they can be operated with ultra-low power dissipation.

Some embodiments address the need for fast electro-optic modulators operating in the near-infrared for use in communications technologies. The quantum-confined Stark effect is an ultra-fast effect, in contrast to the plasma dispersion effect. Additionally, some embodiments do not necessitate current flow for operation, meaning they can be operated with ultra-low power dissipation. Some embodiments employ stannate quantum wells for optical absorption modulation in the visible range.

In the following description, for the purposes of explanation, numerous specific details are set forth in order to provide a thorough understanding of embodiments of the present technology. It will be apparent, however, to one skilled in the art that embodiments of the present technology may be practiced without some of these specific details.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

Multiple quantum wells are currently made using GaAs and aluminium gallium arsenide (AlGaAs) where the quantum well depth is not more than 0.5 eV. Using oxides, the well depth can be extended to a much larger 2-3 eV value. Various embodiments of the present technology address the problem of oxide quantum wells having subband energy separations that are still small even though the wells are deep, because of the high effective mass in the commonly used quantum well oxide semiconductor SrTiO₃. With the use of stannate perovskites—e.g., barium stannate (BaSnO₃) or strontium stannate (SrSnO₃)—which have very low effective mass, the resulting quantum well energy levels have a larger separation making them suitable for visible light photon absorption/emission.

The larger quantum well depth can potentially push quantum well applications to the visible light regime instead of the infrared range it is currently limited to in GaAs-based structures. The energy window within which some embodiments function depends sensitively on the fabrication process. That is, there is a significant chance for considerable device-to-device variations. This will need to be overcome before such devices can be mass-produced. One route for overcoming such variations is with growth techniques such as atomic layer deposition that offer better reproducibility than molecular beam epitaxy. These structures may be used for vertical external cavity surface emitting lasers (VECSELs) and saturable absorber mirrors. They may also be used for making very efficient solar cells.

Multiple quantum well structures can be used in several applications including diode lasers and photodetectors. These structures have also been utilized for controlling laser intensities using voltages via the Franz-Keldysh effect. By controlling the layer asymmetry, one can also turn these structures into non-linear optical elements that can be used for electro-optic devices.

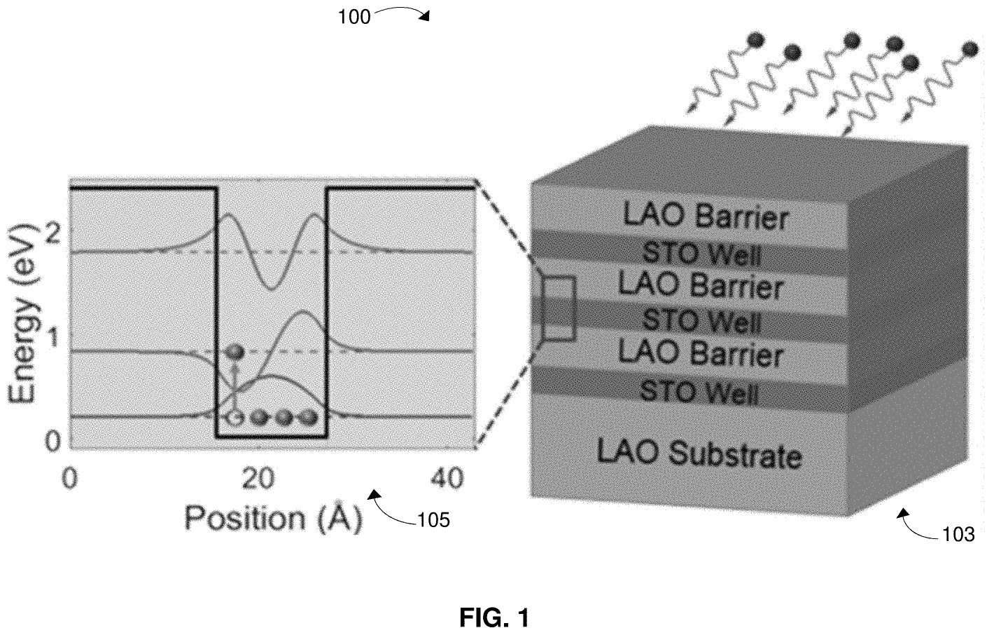

FIG. 1 illustrates an example of an STO/LAO quantum well 100 in accordance with some embodiments of the present technology. In accordance with various embodiments, a multiple quantum well structures 100 can be created based on perovskite oxides as both barrier layers and quantum well layers 103. Specifically, in some embodiments, the barrier layers are wide band gap, high dielectric constant materials, while the quantum well layers are low effective mass, semiconducting oxides. A quantum well 100 is capable of confining electrons or holes in the dimension perpendicular to the surface. This quantum confinement produces a series of energy levels 105 that is tuned by the layer thicknesses and electronic properties.

Various embodiments of the present technology relate generally to electro-optic modulators. Transition metal oxide (TMO) thin films show immense promise for use in a multitude of applications owing to their widely tunable electronic, magnetic, structural and optical properties. Much of the work on TMO thin films has focused on their use in oxide electronics, facilitated by the silicon-compatibility of many perovskite TMO thin films via an epitaxial SrTiO₃ (STO) buffer layer. Accordingly, TMO thin films have featured prominently in the search for new and improved dielectric gate materials for integrated electronics. However, more complex device structures can also be envisioned for TMO thin film heterostructures owing to the plethora of emergent phenomena arising from strong electron correlation in these materials and the potential for band engineering.

One area in which TMO thin films are rapidly gaining prominence is integrated photonics. For decades, lithium niobate (LiNbO₃, or LNO) has been the workhorse material for electro-optic modulators in communications technologies owing to the presence of a robust linear electro-optic effect in LNO. However, the integration of LNO with silicon substrates is not straightforward and the linear electro-optic coefficient of LNO is small relative to other Pockels-active materials. Accordingly, the fabrication of compact, integrated devices from LNO has been challenging, although progress has been made in this area. Recently, the perovskite TMO barium titanate (BaTiO₃, or BTO) has garnered significant research interest for integrated photonics applications owing to its dramatic Pockels response and its epitaxial compatibility with silicon substrates. The existence of a direct epitaxial integration route for BTO significantly reduces the complexity of device fabrication relative to LNO-based integrated devices and is one of the fundamental advantages of perovskite TMO-based integrated photonics devices.

Among this class of silicon-compatible TMO thin film systems, the SrTiO₃/lanthanum aluminate (LaAlO₃), or STO/LAO materials system has attracted special attention due to the discovery of a high-mobility two-dimensional electron gas at the interface of these two band insulators. While a significant effort has been made to utilize the STO/LAO interface in oxide electronics, recent work has focused on the optical properties of the STO/LAO system arising from the large 2.4 eV conduction band offset and the resulting ability to confine charge carriers in STO quantum wells (QWs). In particular, the recent demonstration of room-temperature intersubband absorption in STO/LAO QW heterostructures at terahertz frequencies suggests the potential for STO/LAO QW heterostructures to find use in a variety of integrated photonics devices, including light sources, detectors, and modulators.

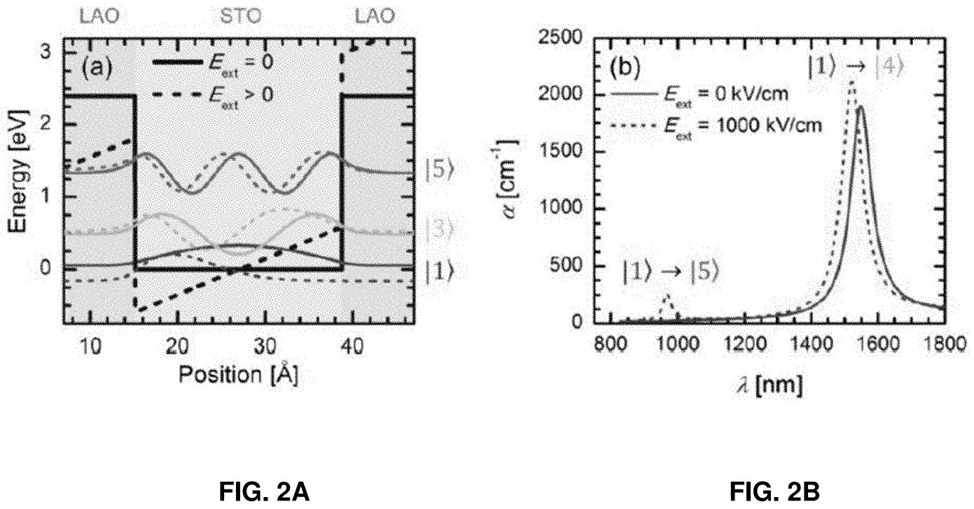

FIG. 2A illustrates calculated wave functions in a 6-unit cell (u.c.) STO QW without (solid lines) and with (dashed lines) an external electric field. The electric field is set to 5×108 V/m. The 0 of energy is set to the bottom of the STO conduction band. For clarity, only the ground state, second excited state and fourth excited states (11), 13), and 15), respectively) are shown in FIG. 2A. An effective mass of m*=1.02me is used for the calculations. FIG. 2B illustrates calculated absorption spectrum of a 6-u.c. STO QW in the near-IR without (solid line) and with (dashed line) an external electric field. The corresponding electron transitions are noted above the absorption peaks. Absorption values are reported for a single QW.

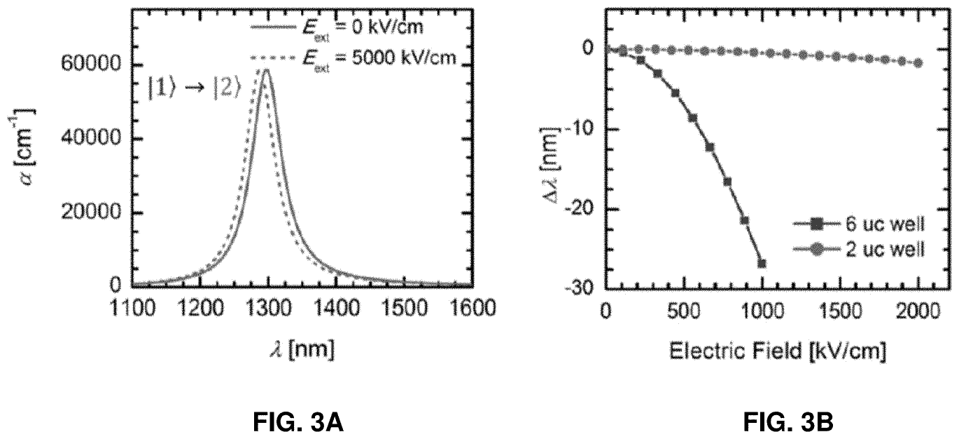

FIG. 3A illustrates calculated absorption spectrum of a 2-u.c. STO QW in the near-IR without (solid line) and with (dashed line) an external electric field. The corresponding electron transition is noted next to the absorption peak. Absorption values are reported for a single QW. An effective mass of m*=1.02me is used for the calculations. FIG. 3B illustrates a change of absorption wavelength Δλ of the |1 [symbol] →|2 [symbol] transition as a function of applied electric field for a six-u.c. QW (red squares) and a two-u.c. QW (blue circles).

The performance of experimentally realizable STO/LAO electro-optic devices exploiting the quantum-confined Stark effect in intersubband absorption for electro-optic operation has been simulated. The wave functions of confined electrons in STO QWs have been calculated and the Stark shifts for a variety of QW geometries have been determined for some embodiments of the present technology. Some embodiments provide for a hybrid silicon-TMO waveguide design for the confinement of an optical mode and simulate the electrical, optical, and electro-optical performance of such a device. Calculated figures of merit include the extent of optical confinement in the electro-optically active TMO layer and the switching energy for modulator devices. Results have demonstrated the feasibility of utilizing the STO/LAO system for electro-optic devices integrated on silicon.

Various embodiments of the present technology provide for a silicon-integrated electro-optic modulator exploiting the quantum-confined Stark effect in SrTiO₃/LaAlO₃ (STO/LAO) quantum wells. Electro-optic modulators are devices that map electrical signals onto optical signals (and vice versa) through some electrical-to-optical coupling mechanism. In some embodiments, that mechanism is the quantum-confined Stark effect in which the characteristic transition energies between quantum-confined electronic states in the STO quantum wells are altered by the application of an external electric field. Transitions between confined electronic states in the STO quantum wells can be induced optically, resulting in optical absorption at the characteristic energy of the transition. The optical transmission through the device at a given wavelength (energy) can then be modulated through the application of an external electric field by shifting the characteristic energy at which light is absorbed. This provides an electrical-to-optical coupling.

Some embodiments of the present technology have several key advantages over current technologies. First, some embodiments are capable of operating at very high speeds of greater than 100 GHz through proper engineering efforts. Second, devices can be engineered with ultra-low power consumption because electrical current is not required for operation. Finally, ultra-compact devices can be made, in contrast to large resonators and Mach-Zehnder interferometer designs used for traditional plasma dispersion-based devices. The compactness of electro-optic devices is becoming an increasingly critical design component due to the need for dense device arrays in photonic integrated circuits.

The energy window within which some embodiments function depends sensitively on the fabrication process. That is, there is a significant chance for considerable device-to-device variations. This will need to be overcome before such devices can be mass-produced. One route for overcoming such variations is with growth techniques such as atomic layer deposition that offer better reproducibility than molecular beam epitaxy.

Electron wave functions in the STO QWs have been calculated within the effective-mass approximation using a Poisson-Schrödinger solver. Optical absorption spectra were computed from the calculated wave functions according to the method detailed in M. Helm, “Chapter 1 The Basic Physics of Intersubband Transitions,” in Semiconductors and Semimetals (1999), 62, pp. 1-99, which is hereby incorporated by reference in its entirety for all purposes.

Finite element simulations were conducted using COMSOL Multiphysics. The STO/LAO QW heterostructures were modeled as a single thin film of thickness t_{TMO} with optical index of refraction and electrical permittivity given by the weighted average of the STO and LAO permittivities according to the relative thicknesses of the STO and LAO layers. Mode simulations were carried out utilizing the mode analysis method in the RF module. The perfect electrical conductor boundary condition was applied to the edges of the 2D simulation cell, a reasonable approximation given the tight confinement of the optical mode to the hybrid silicon-TMO waveguide. Electrical simulations were conducted using the AC/DC module with the charge conservation boundary condition applied to the boundaries of the 2D simulation cell.

Many electro-optic devices relying on intersubband transitions, including modulators, photodetectors, and lasers have been studied using the GaAs/AlGaAs materials system. However, the small conduction band offset in this system limits the energy with which such intersubband transitions can occur to typically the mid- or far-IR range. The large conduction band offset in the STO/LAO system, on the other hand, allows for operation at much shorter wavelengths, including those in the near-IR utilized in communications technologies. Furthermore, the ease with which STO/LAO QW heterostructures can be integrated with silicon substrates via direct epitaxial deposition supports the use of such devices in photonic integrated circuits.

The calculated electronic wave functions in an STO/LAO QW with the six-unit cell (u.c.) thick well layer (FIG. 2A) show that the energy spacing between confined states can significantly exceed 1 eV and enter the near-IR. The effect of an external electric field Eₑₓₜ on the wave functions can also be observed. As expected, the ground state wave function experiences the most significant change in energy ΔE₁≈250 meV as a result of the quantum-confined Stark effect. The shift in energy of the confined states is also clearly seen in the near-IR absorption spectrum of the QW (FIG. 2B). Notably, the ground state-to-third-excited state (|1 [symbol] →|4 [symbol] ) transition is predicted to occur near the common telecom wavelength of approximately 1550 nm. This estimate corresponds to the case where the QW is doped to only populate the ground state in the calculation of the absorption spectrum in FIG. 2B.

While a six-u.c. thick QW is predicted to produce intersubband transitions near 1550 nm, transitions near the other critical telecom wavelength of 1300 nm can likely also be realized by utilizing other QW geometries. For example, our calculations suggest a transition energy of approximately 1300 nm in a two-u.c. thick QW (FIG. 3A). Such a narrow well confines just two electronic states, leaving us with only the |1 [symbol] to |2 [symbol] transition. However, because the ground state wave function is pushed farther from the conduction band bottom as the well becomes narrower, the transition energy in the two-u.c. well experiences a smaller Stark shift than the six-u.c. well (FIG. 3B). As a result, the utility of such narrow structures in devices requiring electro-optic switching will be limited as the fields required for switching may become prohibitively large.

It should be noted that there is some uncertainty in the predicted intersubband transition energies arising from uncertainty in the electron effective mass within the STO QW. The effective mass in STO can vary as a function of doping and strain and is also band-dependent. However, calculated values represent a good approximation to the expected intersubband transition energies as an effective mass value has been in the calculations that is consistent with the latest theoretical and experimental results for strained, lightly-doped STO films.

In order to utilize the near-IR intersubband transitions in STO/LAO QWs in integrated electro-optic devices, any device concept must conform to a few design rules. Firstly, the device must allow an external electric field to be applied normal to the QW layers. Only components of the external electric field normal to the QW layers will alter the confining potential and lead to Stark shifts of intersubband transition energies. Secondly, the waveguide must support a transverse magnetic (TM) optical mode. Due to a polarization selection rule, intersubband transitions between confined states can only be induced by the component of the optical electric field that is normal to the plane of the QW. Therefore, any devices hoping to make use of intersubband absorptions for operation, such as electro-optic modulators, switches, or photodetectors, require a TM optical mode.

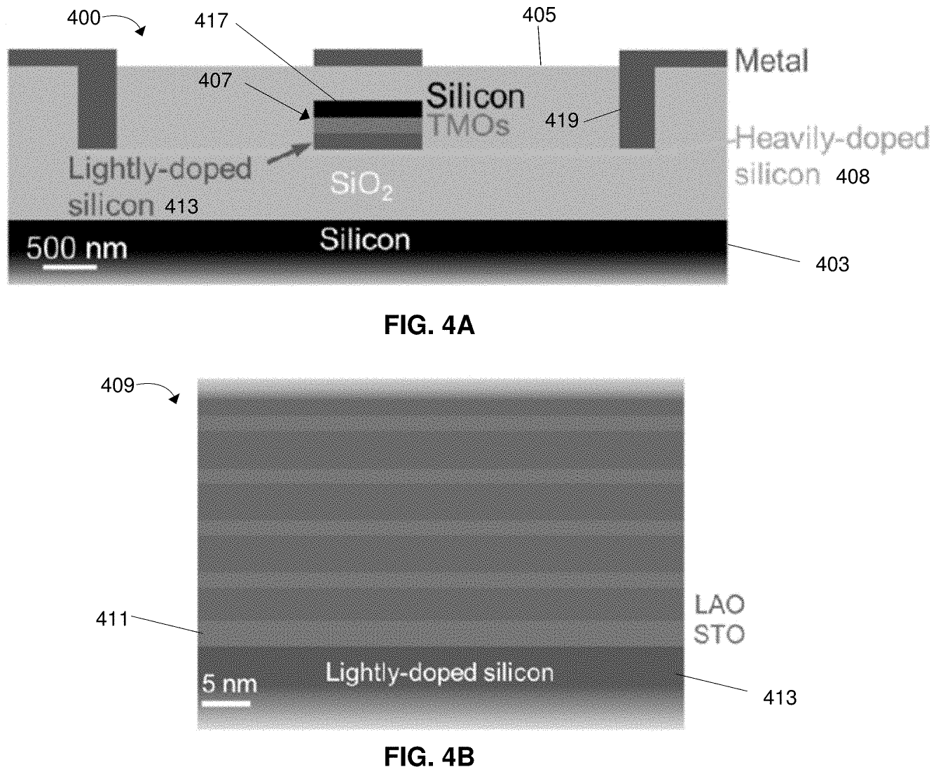

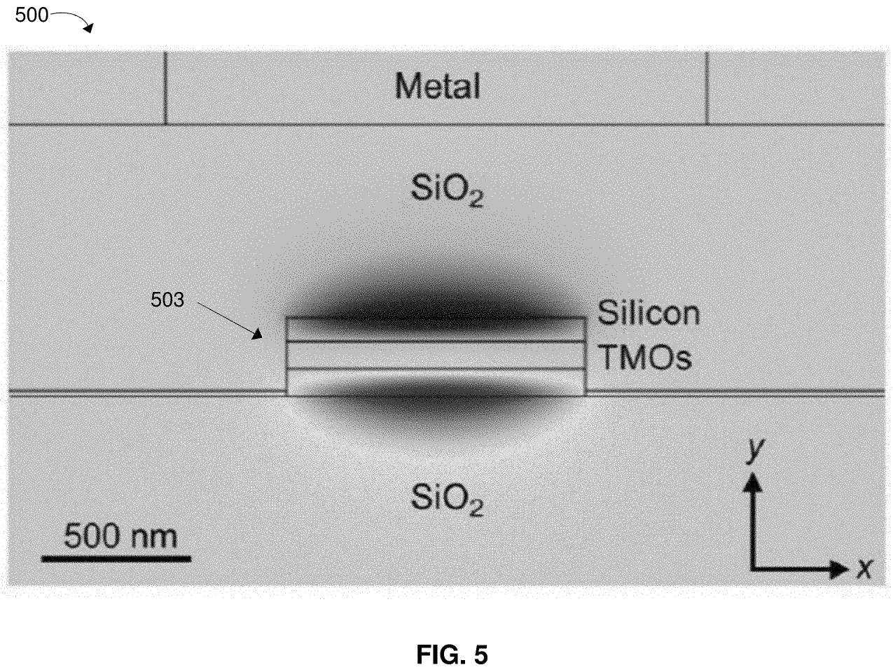

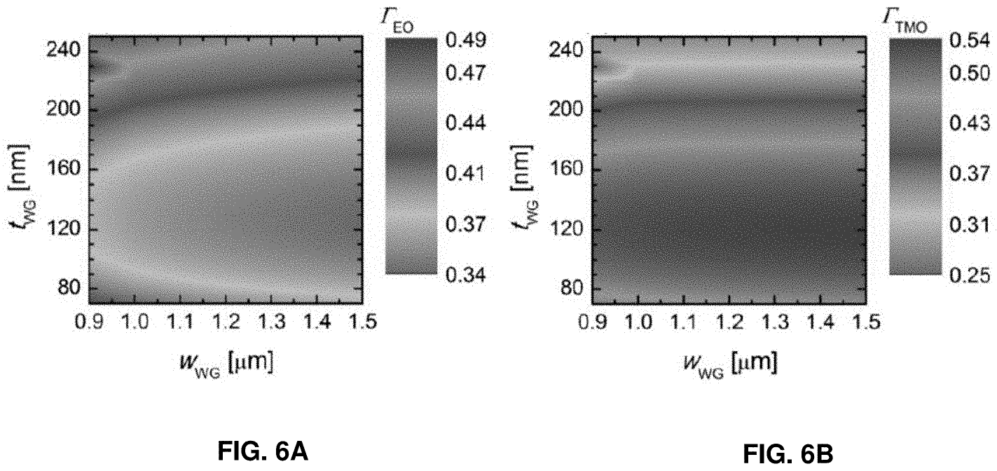

FIG. 4A is a block diagram illustrating a device structure 400 for STO/LAO electro-optic devices. Fabrication would begin from a silicon-on-insulator (SOI) wafer 403. The STO/LAO QW heterostructure 405 would be epitaxially deposited on ion-implanted SOI wafer and then etched to form the hybrid TMO-silicon waveguide 407 shown. FIG. 4B illustrates a zoom-in of STO/LAO QW heterostructure 409 integrated on silicon via an epitaxial STO buffer layer 411. In the embodiments illustrated in FIGS. 4A and 4B. device structure 400 (FIG. 4A) features a STO/LAO QW superlattice epitaxially integrated on a lightly-doped silicon layer 413 (FIG. 4B) to form a hybrid TMO-silicon waveguide 407. Waveguide 407 may be formed on a heavily-doped silicon layer 408 formed on in a silicon dioxide layer 415 formed on the silicon layer 403, with the lightly-doped silicon layer 413 formed on the heavily-doped silicon layer 408, and then alternating layers of TMOs formed on the lightly-doped silicon layer 413. In some embodiments, another silicon layer 417 may be formed on the alternating layers of TMOs, as shown in FIG. 4A. Further silicon dioxide may then be deposited or otherwise formed on one or more of the silicon layer 403, the heavily-doped silicon layer 408, and the silicon-TMO waveguide 407. Metal structure(s) 419 may be further formed as shown in FIG. 4A. The lightly-doped silicon layer 413 can then be used as an integrated bottom electrode, reducing the distance between the electrodes and thereby reducing the voltage required to realize a given electric field across the QWs. The resulting external electric field is normal to the QWs, allowing for the realization of quantum-confined Stark shifts. Furthermore, the hybrid TMO-silicon waveguide 407 supports a TM mode (see, e.g., FIG. 5), allowing for the optical stimulation of intersubband transitions.

FIG. 5 demonstrates simulated fundamental TM mode 500 in a hybrid TMO-silicon waveguide 503 with waveguide width 1 μm, top silicon thickness 90 nm and TMO thickness 100 nm. The color scale represents the z-component of the optical electric field where green is zero field, blue is negative field and red is positive field.

Although these embodiments of the device structure require several processing steps for fabrication, similar electro-optic devices have been successfully fabricated using cleaved LNO as the electro-optically active layer. In some embodiments, STO/LAO QWs could form the electro-optically active layer. Such QW heterostructures can be grown via epitaxial techniques such as molecular beam epitaxy, pulsed laser deposition, or atomic layer deposition. In some embodiments, the device could require additional processing steps in order to etch the TMO layers and form the hybrid TMO-silicon waveguide depicted in FIG. 4A. However, such a device should be experimentally realizable with focused processing efforts following additional efforts (see, e.g., L. Chen, M. G. Wood, and R. M. Reano, “12.5 pm/V hybrid silicon and lithium niobate optical microring resonator with integrated electrodes,” Opt. Express 21(22), 27003 (2013), which is hereby incorporated by reference in its entirety for all purposes).

Two figures of merit are particularly important when evaluating the performance of an electro-optic device of various embodiments: the electro-optic overlap integral Γ_{EO} and the optical confinement in the electro-optically active TMO layer Γ_{TMO}. The electro-optic overlap Γ_{EO} is a normalized measure of the interaction between the optical mode confined in the waveguide and the external electric field and is defined as

$${Γ}_{E O} = \frac{S}{V} \frac{\int \int {E}_{opt}^{2} ( x , y ) {E}_{e x t} ( x , y ) dxdy}{\int \int {E}_{opt}^{2} ( x , y ) dxdy}$$

where S is the distance between the top and bottom electrodes, V is the applied voltage, Eₑₓₜ is the external electric field and Eₒₚₜ is the electric field of the confined optical mode. (see, e.g., C. M. Kim and R. V. Ramaswamy, “Overlap integral factors in integrated optic modulators and switches,” J. Light. Technol. 7(7), 1063-1070 (1989), which is hereby incorporated by reference in its entirety for all purposes). A larger Γ_{EO} value indicates greater overlap between the applied electric field and the optical mode and therefore more efficient electro-optic switching.

The TMO optical confinement Γ_{TMO} is a normalized measure of the amount of the optical signal present in the electro-optically active TMO layer and is defined as

$${Γ}_{T M O} = \frac{\int {\int }_{T M O} {E}_{opt}^{2} ( x , y ) dxdy}{\int {\int }_{A l l} {E}_{opt}^{2} ( x , y ) dxdy}$$

where the integral in the numerator is only evaluated over the area of the TMO layer while the integral in the denominator is evaluated over the entire device area. Γ_{TMO} therefore indicates the relative fraction of the optical mode that is available to interact with confined electrons in the QW (e.g., for absorption). In an absorption-based device such as a modulator or a switch, Γ_{TMO} manifests itself in the extinction ratio of the optical absorption as light that is not confined within the TMO layer will not be absorbed and will therefore be confined to the background output optical signal.

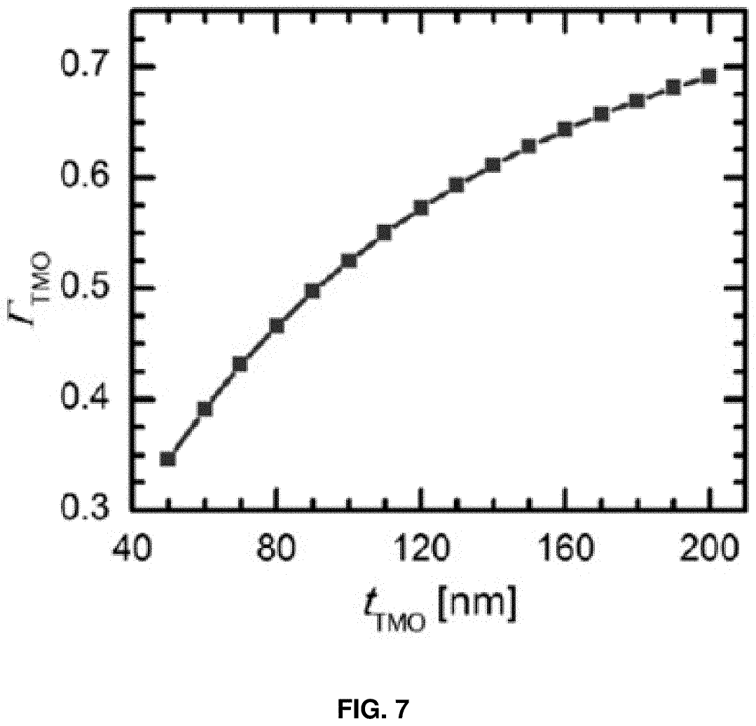

FIG. 6A is a plot illustrating electro-optic overlap integral Γ_{EO} and FIG. 6B is a plot illustrating TMO optical confinement Γ_{TMO} as a function of waveguide width w_{WG} and top silicon thickness tWG for a hybrid TMO-silicon waveguide structure with total TMO thickness t_{TMO}=100 nm. Both Γ_{EO} and Γ_{TMO} can be modified by changing the waveguide width w_{WG} and the thickness of the top silicon layer t_{WG} (FIGS. 6A and 6B). In general, there is a tradeoff between the two figures of merit, with Γ_{EO} increasing and Γ_{TMO} decreasing as the top silicon thickness is increased. This tradeoff can be easily explained by the changing mode shape associated with altering the waveguide dimensions. As the top silicon is made thicker, the optical mode is pulled more into the silicon, decreasing Γ_{TMO}. At the same time, the mode becomes more confined laterally due to the large index contrast between silicon and the surrounding materials, increasing the electro-optic overlap integral Γ_{EO}. The lateral confinement of the mode also increases as the waveguide width decreases, resulting in the observed behavior of increasing Γ_{EO} as w_{WG} decreases for a given tWG. The calculated values of Γ_{TMO} are competitive with other TMO-based electro-optic devices while our calculated values of Γ_{EO} are somewhat smaller. However, it should be noted that the exact values of Γ_{EO} and Γ_{TMO} are dependent on the specific device design one chooses, which may differ from the one suggested in FIGS. 4A and 4B without departing from the scope and spirit of the present technology.

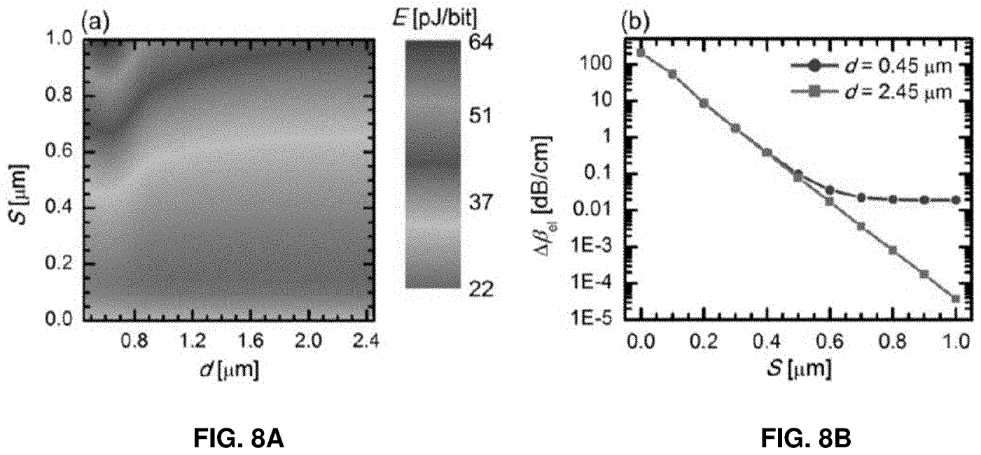

FIG. 7 is a plot illustrating simulated TMO optical confinement Γ_{TMO} as a function of TMO thickness t_{TMO} for a hybrid TMO-silicon waveguide with w_{WG}=1 μm and t_{WG}=90 nm. In addition to the waveguide dimensions, the thickness of the TMO heterostructure t_{TMO} also impacts Γ_{TMO} with thicker heterostructures resulting in increased optical confinement within the TMO layer (FIGS. 5A and 5B). In principle, the epitaxial deposition of STO/LAO QW heterostructures of arbitrary thickness should be possible, although the exploration of such structures on silicon substrates has only begun rather recently. In any case, by controlling the waveguide dimensions and TMO thickness, one can control the device performance as characterized by the electro-optic overlap Γ_{EO} and the TMO optical confinement Γ_{TMO}.

As a specific example of an electro-optic device exploiting the quantum-confined Stark effect in the STO/LAO system, consider an electro-optic modulator utilizing the device geometry presented in FIGS. 4A and 4B. Such a modulator could operate in the near-IR where the modulated signal is given by the electric field-induced change in optical absorption at a given wavelength, as calculated, e.g., in FIG. 3B or FIG. 4A. The quantum-confined Stark effect is an excellent mechanism for the construction of an electro-optic modulator due to the high-speed nature of the electric field-induced energy level shifts. High-speed operation should therefore be possible in such a device.

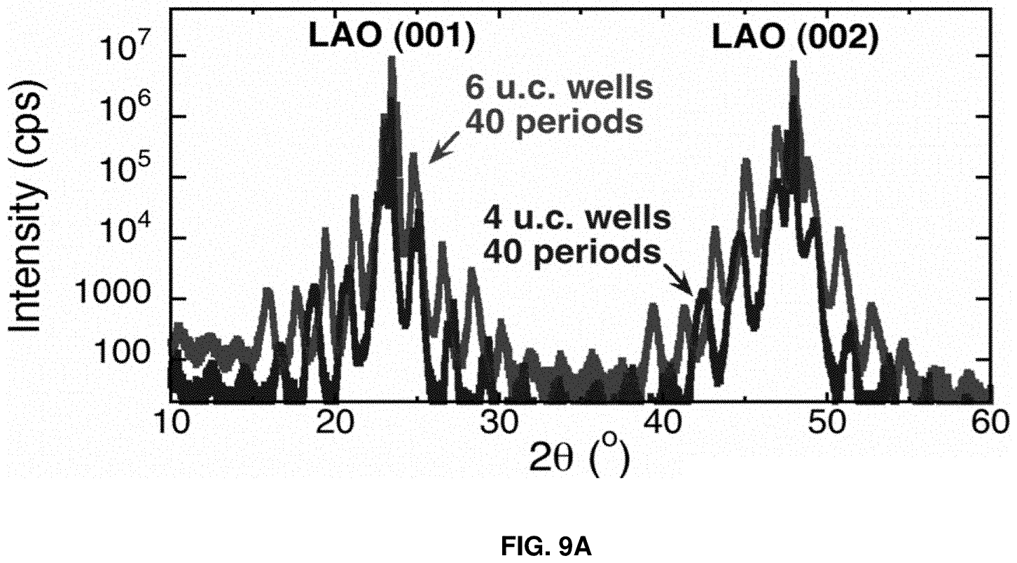

FIG. 8A is a plot illustrating calculated switching energy E of an STO/LAO electro-optic modulator as a function of lateral and vertical waveguide-to-electrode spacing, Band S, respectively. Calculations assume electrode lengths of 100 μm and an electric field of 1000 kV/cm across the STO/LAO layer for switching. FIG. 8B illustrates calculated additional optical absorption due to the electrodes Δβel as a function of S for d=0.45 μm (red circles) and d=2.45 μm (blue squares).

The modulation energy E of an electro-optic modulator in units of J/bit is given by

$$E = \frac{1}{4} C {V}_{D}^{2}$$

where C is the device capacitance and V_{D} is the drive voltage. From the above equation, we can see that the energy consumption is most directly impacted by the electrode geometry insofar as the electrode geometry impacts the device capacitance and the needed drive voltage. For the device geometry in FIGS. 4A and 4B, V_{D} is tied to the vertical waveguide-to-electrode distance S, while C is related to both S and the lateral waveguide-to-electrode spacing d. By appropriately tuning S and d, the modulation energy can be minimized (FIG. 8A). However, by bringing the electrodes closer to the waveguide, one may induce additional optical absorption Δβₑₗ due to the interaction between the optical mode and the metallic electrodes (FIG. 8B).

The calculations in FIGS. 8A and 8B suggest that the lateral waveguide-to-electrode distance d should be made large when constructing an electro-optic modulator using the design shown in FIGS. 4A and 4B. A large value of d minimizes the capacitance between electrodes in the lateral direction, thereby reducing the switching energy. Furthermore, for S>0.4 μm, a larger value of d corresponds to reduced optical absorption from the electrodes, while the optical absorption is dominated by the top electrode regardless of the lateral electrode spacing for S≤0.4 μm.

While the exact values of switching energy are dependent on extrinsic factors, such as device length and electrode design, calculations suggest switching energies on the order of pJ/bit are possible in the STO/LAO electro-optic modulators. This value is competitive with switching energies in some silicon Mach-Zehnder modulators, although recent reports of compact silicon ring modulators have reduced the switching energy considerably into the sub-fJ/bit range. The switching energies in STO/LAO modulators are primarily dependent on the rather high electric fields needed to sufficiently modulate the optical absorption energy. By optimizing modulator design such that the voltage needed to reach the switching field can be reduced, the switching energy can be significantly reduced.

Various embodiments of STO/LAO electro-optic modulators also have the advantage that they could likely be fabricated with a relatively small device footprint. Lateral device sizes of approximately 3 μm should be possible, with the lateral electrode spacing and the waveguide width defining the critical feature sizes in the lateral direction. Additionally, only a single, straight waveguide is necessary for the operation such a device. This contrasts with ring resonators or Mach-Zehnder interferometers in which interference of the optical signals between two or more waveguides is required, thereby increasing device footprint. The straight, narrow geometry of the proposed STO/LAO electro-optic modulators should therefore allow for dense device packing.

The calculations above support the feasibility of producing integrated electro-optic devices operating at terahertz optical frequencies based on the STO/LAO materials system. Such devices achieve electro-optic operation by utilizing the quantum-confined Stark effect to modulate the energy of intersubband transitions in the STO conduction band and could be constructed using existing thin film growth and semiconductor processing techniques. As a specific example, calculations of the switching energy in an STO/LAO electro-optic modulator integrated on silicon have been shown. Such modulators have the potential for high-speed operation due to the short time scales needed for electronic energy level modulation by the quantum-confined Stark effect. Additionally, electro-optic devices based on the Stark effect can be engineered for low power operation because the Stark effect is field-driven and does not necessitate current flow for operation. These results open the door for the fabrication of new electro-optic devices capable of operating in the near-IR and suggest the possibility of integrating a wide range of TMO thin films and heterostructures into electro-optic device architectures in order to take advantage of the multitude of emergent phenomena in such materials.

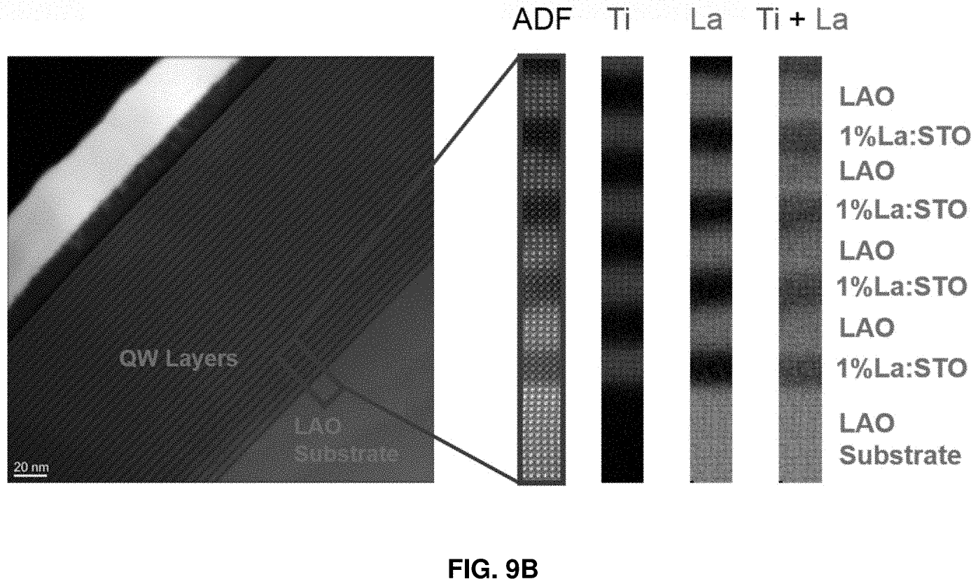

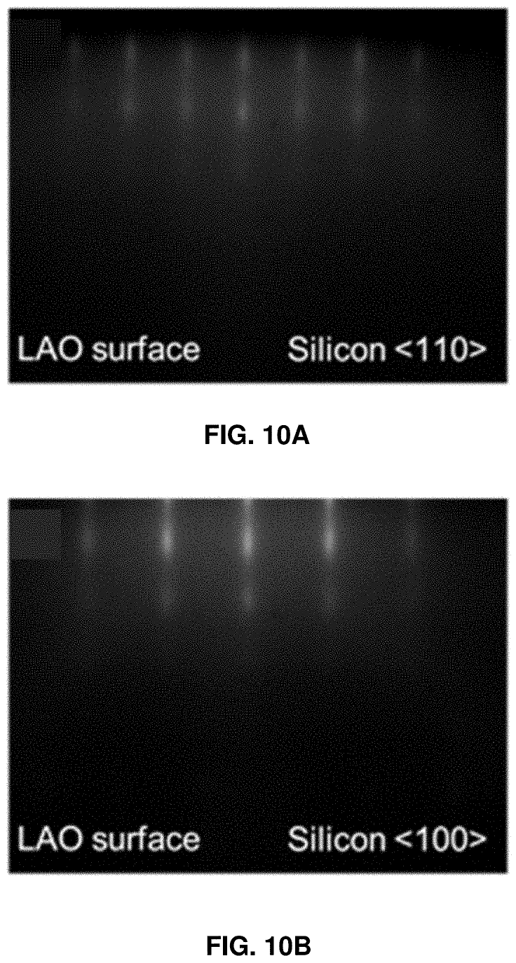

FIG. 9A is an x-ray diffraction (XRD) 2θ plot for a heterostructure built in accordance with one or more embodiments of the present technology. FIG. 9B shows a cross-section transmission electron microscope image of the quantum well layers and LAO substrate according to some embodiments of the present technology. As can be seen from FIGS. 9A and 9B, the issues of traditional structures (e.g., interfacial defects and difficulty growing thick heterostructures) have been overcome. The XRD plot in FIG. 9A shows a clear superlattice peaks and the STEM imaging in FIG. 9B demonstrates clear separation between layers with no thickness-dependent degradation.

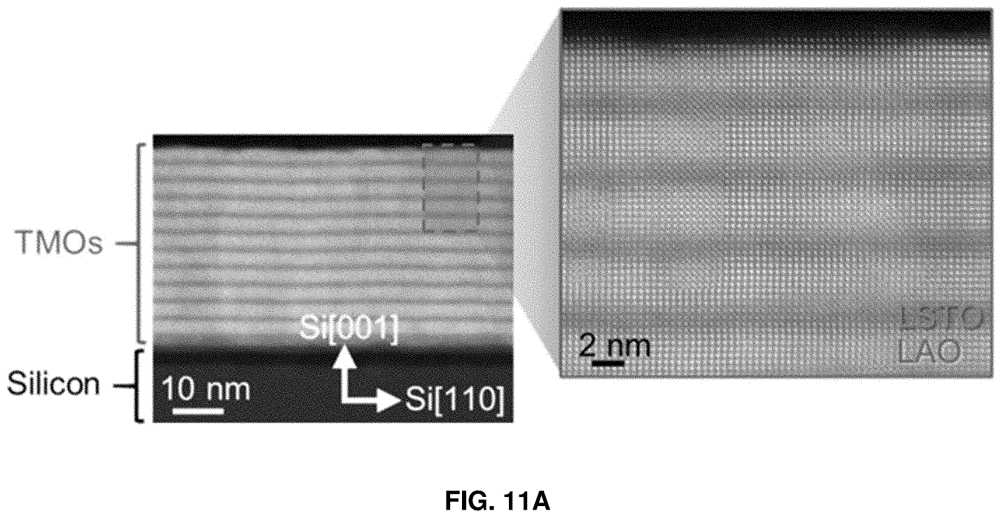

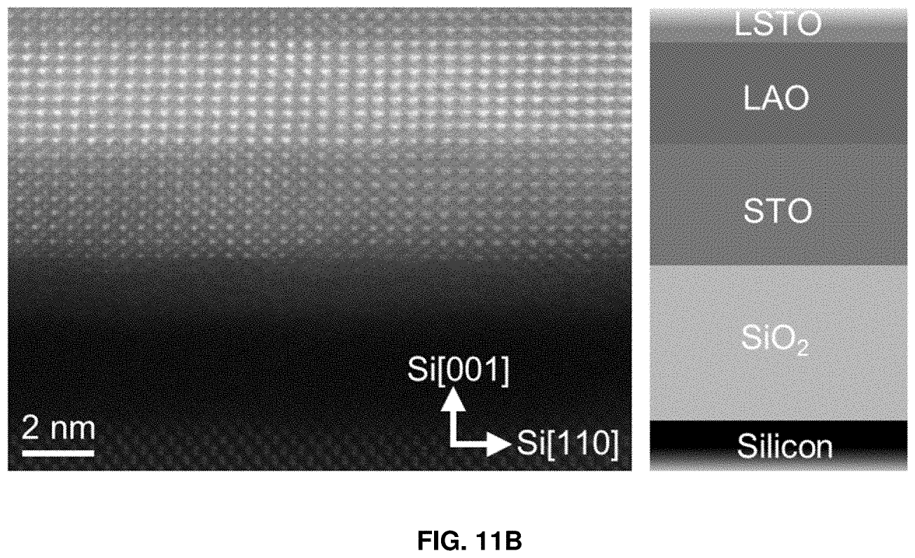

FIGS. 10A and 10B are RHEED patterns of an STO/LAO quantum well on silicon via STO buffer layer in accordance with various embodiments of the present technology. As evidenced in FIGS. 10A and 10B, there is no evidence of thickness-dependent degradations of the crystalline surface even after ˜400 Angstroms. As such, thicker structures are possible. FIGS. 11A and 11B show STEM images with a clear STO/LAO separation, where “LSTO” signifies lanthanum-doped strontium titanate.

Oxide quantum well superlattices, could find use in a variety of applications, including light sources, photodetectors and optical mirrors. Moreover, quantum well structures based on III-V semiconductors are typically used in efficient lasers, photodetectors, modulators and switches. The ability to make multiple quantum wells of arbitrary thickness on an oxide materials platform allows for several advantages. First, extreme tolerance for strain/lattice mismatch allows for a wider variety of materials to be stacked. This means unprecedented control over band offsets, effective masses and subband spacing. Quantum well devices can now be pushed to operate in the visible light regime. III-V quantum wells are limited to near infrared. These stacks can be straightforwardly integrated on silicon unlike III-V systems which require complicated graded buffers or wafer bonding.

Devices based on oxide quantum wells include, but are not limited to the following: 1) Double heterostructure lasers operating in visible range; 2) Vertical cavity surface emitting lasers (VCSELs) operating in the visible range; 3) Tunable VCSELs; 4) Highly efficient quantum well photodetectors using oxide superlattices for visible light detection; and 5) Self Electro-optic Effect Devices (SEEDs).

A double heterostructure laser operating in the visible range can be created using material with smaller direct band gap and low effective mass sandwiched between materials with wide band gap. The potential barriers on either side confines the charge carriers in the well region. Vertical cavity surface emitting lasers (VCSELs) operating in the visible range can be created using multiple quantum well structures and are additionally clad by semiconducting distributed Bragg reflectors (DBR) on the top and bottom. This is a much more complicated structure that requires dozens of quantum wells and the ability to dope the mirror layers both n-type and p-type.

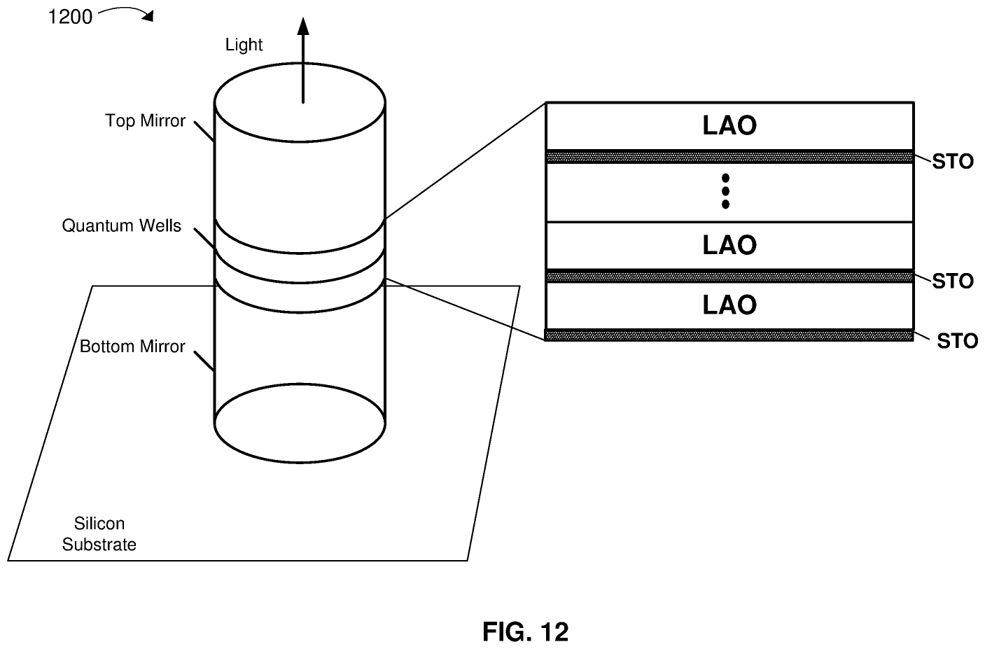

FIG. 12 illustrates an example of a basic VCSEL 1200 in accordance with some embodiments of the present technology. Tunable VCSELs can be created in some embodiments using piezoelectric or piezooptic effects. The Bragg reflectors can be adjusted using electrical or optical inputs. A 2D array of tunable VCSELs in visible could be used in display technology, for example.

In some embodiments, highly efficient photodetectors using superlattices can be created by using the energy level differences of the subbands, which can be in the hundreds of meV for oxide superlattices (instead of ˜100 meV for GaAs). Very sensitive detectors for red or near IR light can be made. Current devices are limited to far infrared (quantum well infrared photodetector or QWIP).

Modulators can be made based on various embodiments of the LAO/STO superlattice using the quantum confined Stark effect. Self-electro-optic effect devices (SEEDs) can be used for optical logic gates in some embodiments. This requires complicated structures and combines photodiodes with electro-optic modulators and intervening electrical circuitry. This allows for multi-state optical switching without the need to convert to binary electrical signals. Combined with waveguides and intrinsic Pockels effect, this can be made very compact and orders of magnitude smaller than free-space equivalents which are macroscopic.

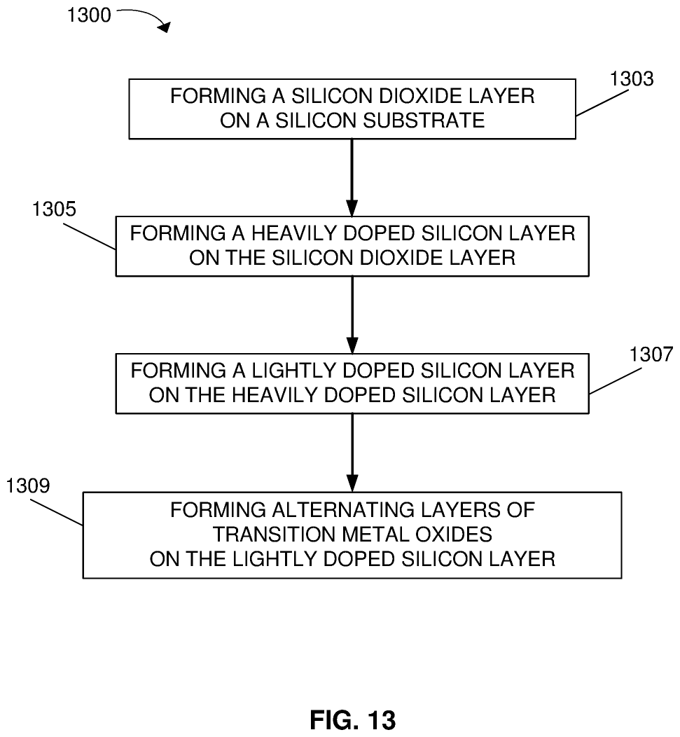

FIG. 13 is a flow chart of a method 1300 for manufacturing a quantum well heterostructure (e.g., structure 400 as shown in FIGS. 4A and 4B) according to one or more embodiments of the present technology. Referring to FIG. 13, along with the foregoing figures and description, method 1300 includes the step of forming 1303 a silicon dioxide layer on a silicon substrate. Method 1300 includes the step of forming 1305 a heavily-doped silicon layer in or on the silicon dioxide layer. Method 1300 includes the step of forming 1307 a lightly-doped silicon layer on the heavily-doped silicon layer. Method 1300 includes the step of forming 1309 alternating functional layers of TMOs and silicon on the lightly-doped silicon layer.

In one embodiment, the method 1300 step of forming 1309 alternating functional layers of TMOs on the heavily-doped silicon layer includes forming the alternating layers of TMOs having equal thicknesses. In an example, equal thicknesses of the alternating layers of TMOs may vary in their thicknesses by a tolerance, while still being considered to have substantially equal thicknesses. The tolerance may be +/−0.05%, +/−0.1%, +/−0.5%, +/−1%, or +/−0.001% to +/−10%.

In another embodiment, the method 1300 step of forming 1309 alternating functional layers of TMOs on the heavily-doped silicon layer includes forming the alternating layers of TMOs with at least one of the alternating layers having a thickness that is different from a thickness of at least one other one of the alternating layers.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for”, but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

1. A device comprising:
a silicon substrate;
a silicon dioxide layer formed on the silicon substrate;
a doped silicon layer on which is built a heterostructure created from alternating functional layers of transition metal oxides (TMOs) and silicon.

2. The device of claim 1, wherein the TMOs include strontium titanate.

3. The device of claim 1, wherein the heterostructure is a quantum well created from perovskite oxides as both barrier layers and quantum well layers.

4. The device of claim 3, wherein the barrier layers are wide band gap, high dielectric constant materials.

5. The device of claim 4, wherein the quantum well layers are low effective mass, semiconducting oxides.

6. The device of claim 5, wherein the low effective mass, semiconducting oxides include stannate perovskites.

7. The device of claim 5, wherein the semiconducting oxides include barium stannate or strontium stannate.

8. The device of claim 3, wherein the quantum well confines electrons or holes in a dimension perpendicular to a surface of the heterostructure.

9. The device of claim 3, wherein the quantum well has a depth of two to three electron volts.

10. The device of claim 3, wherein the quantum well has energy levels with a separation sufficient to enable visible light photon absorption or emission.

11. The device of claim 1, wherein the heterostructure created from the alternating functional layers of TMOs and silicon creates an electro-optic modulator.

12. The device of claim 1, wherein the heterostructure is a hybrid silicon-TMO waveguide.

13. The device of claim 12, wherein the hybrid silicon-TMO waveguide supports a transverse magnetic optical mode.

14. The device of claim 1, wherein the alternating functional layers of TMOs are created via atomic layer deposition or molecular beam epitaxy.

15. The device of claim 1, wherein the doped silicon layer is a heavily doped silicon layer.

16. The device of claim 15 further comprising a lightly doped silicon layer between the heavily doped silicon layer and the alternating functional layers of TMOs.

17. An electro-optic modulator comprising:
a silicon substrate;
a silicon dioxide layer formed on the silicon substrate;
a doped silicon layer; and
a thin film transition metal oxide (TMO) heterostructure of multiple quantum wells created from alternating layers of strontium titanate and lanthanum aluminate built on the doped silicon layer.

18. The electro-optic modulator of claim 17, wherein the multiple quantum wells include barrier layers that are wide band gap, high dielectric constant materials.

19. The electro-optic modulator of claim 17, wherein the multiple quantum wells have quantum well layers formed of low effective mass, semiconducting oxides.

20. The electro-optic modulator of claim 19, wherein the low effective mass, semiconducting oxides include stannate perovskites.

21. The electro-optic modulator of claim 19, wherein the low effective mass, semiconducting oxides include barium stannate or strontium stannate.

22. The electro-optic modulator of claim 17, wherein the multiple quantum wells confine electrons or holes in a dimension perpendicular to a surface of the thin film TMO heterostructure.

23. The electro-optic modulator of claim 17, wherein at least some of the multiple quantum wells have a depth of two to three electron volts.

24. The electro-optic modulator of claim 17, wherein at least some of the multiple quantum wells have energy levels with a separation sufficient to enable visible light photon absorption or emission.

25. The electro-optic modulator of claim 17, wherein the thin film TMO heterostructure supports a transverse magnetic optical mode allowing the electro-optic modulator to make use of intersubband absorptions.

26. The electro-optic modulator of claim 17, wherein the doped silicon layer is a heavily doped silicon layer.

27. The electro-optic modulator of claim 26 further comprising a lightly doped silicon layer between the thin film TMO heterostructure.

28. The electro-optic modulator of claim 17, wherein the thin film TMO heterostructure provides quantum-confined Stark effect in intersubband absorption for electro-optic operation.

29. A method comprising:
forming a silicon dioxide layer on a silicon substrate;
forming a doped silicon layer in or on the silicon dioxide layer; and
forming alternating layers of functional transition metal oxides (TMOs) on the doped silicon layer.

30. The method of claim 29, wherein the doped silicon layer comprises a heavily doped silicon layer, the method further comprising forming a lightly doped silicon layer on the heavily doped silicon layer.

31. The method of claim 30, wherein forming alternating layers of functional TMOs on the doped silicon layer comprises forming the alternating layers of functional TMOs on the lightly doped silicon layer.

32. The method of claim 29 further comprising forming a layer of silicon on the doped silicon layer.

33. The method of claim 29 wherein forming alternating layers of functional TMOs on the doped silicon layer comprises forming the alternating layers of functional TMOs having equal thicknesses.

34. The method of claim 29 wherein forming alternating layers of functional TMOs on the doped silicon layer comprises forming the alternating layers of functional TMOs with at least one of the alternating layers having a thickness that is different from a thickness of at least one other one of the alternating layers.
